(19) United States
(12) Patent Application Publication
(10) Pub. No.: US 2026/0090147 A1
(43) Pub. Date: Mar. 26, 2026

(54) DISPLAY DEVICE

(71) Applicant: AUO Corporation, Hsinchu City (TW)

(72) Inventors: Chia-An Lee, Hsinchu City (TW); Yu-Hsin Huang, Hsinchu City (TW); Wen-Wei Yang, Hsinchu City (TW); YinYu Chen, Hsinchu City (TW); Yi-Hong Chen, Hsinchu City (TW); Kuan-Heng Lin, Hsinchu City (TW)

(73) Assignee: AUO Corporation, Hsinchu City (TW)

(21) Appl. No.: 18/953,049

(22) Filed: Nov. 19, 2024

(30) Foreign Application Priority Data
Sep. 26, 2024 (TW) 113136684

(51) Int. Cl. H01L 33/38; H01L 33/22; H01L 33/54; H01L 33/62

(52) U.S. Cl. CPC H10H 20/8314; H10H 20/82; H10H 20/853; H10H 20/857

(57) ABSTRACT

Provided is a display device including a substrate and multiple display pixels on the substrate. Each display pixel includes a light emitting unit and an insulating layer. The light emitting unit includes a first ohmic contact metal, a light emitting diode, and a second ohmic contact metal that are disposed in sequence in a direction away from the substrate. The insulating layer is disposed on at least a side of the light emitting diode, and includes a first protruding portion, where a distance between the first protruding portion and the substrate is greater than or equal to a distance between a top surface of the light emitting diode and the substrate. A part of the second ohmic contact metal is disposed on a first side wall of the first protruding portion facing the light emitting diode.

### CROSS-REFERENCE TO RELATED APPLICATION

This application claims the priority benefit of Taiwan application serial no. 113136684, filed on Sep. 26, 2024. The entirety of the above-mentioned patent application is hereby incorporated by reference herein and made a part of this specification.

### BACKGROUND

### Technical Field

This disclosure relates to a display device.

### Description of Related Art

Conventional vertical light emitting diodes generally have the problem that their light emitting surfaces are shaded by the electrodes above them, in addition to the problem of light leakage from the large viewing angle, the half-intensity viewing angle is too large, which reduces the quality of the display.

### SUMMARY

The disclosure provides a display device, capable of avoiding light leakage at a large viewing angle and has sufficient forward light emission.

According to an embodiment of the disclosure, a display device including a substrate and multiple display pixels disposed on the substrate is provided. Each of the display pixels includes a light emitting unit and an insulating layer. The light emitting unit includes a first ohmic contact metal, a light emitting diode, and a second ohmic contact metal disposed sequentially in a direction away from the substrate, where the first ohmic contact metal and the second ohmic contact metal are respectively connected to the light emitting diode. The insulating layer is disposed on at least one side of the light emitting diode and includes a first protruding portion, where a distance between the first protruding portion and the substrate is greater than or equal to a distance between a top surface of the light emitting diode away from the substrate and the substrate. A part of the second ohmic contact metal is disposed on a first side wall of the first protruding portion facing the light emitting diode.

Based on the above, the display device provided by the embodiment of the disclosure is configured with a protruding portion that is higher than the top surface of the light emitting diode, and an ohmic contact metal is disposed on the side wall of the protruding portion facing the light emitting diode. Utilizing the property of high reflectivity of the ohmic contact metal in the visible light band, the light from the light emitting diode is reflected. Accordingly, the light leakage of the display device at a large viewing angle is reduced, and the forward light emission of display device is improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 shows a schematic diagram of a display device according to an embodiment of the disclosure.

FIG. 2 shows a schematic diagram of a display device according to an embodiment of the disclosure.

FIG. 3 shows structural parameters of a display device according to an embodiment of the disclosure.

### DESCRIPTION OF THE EMBODIMENTS

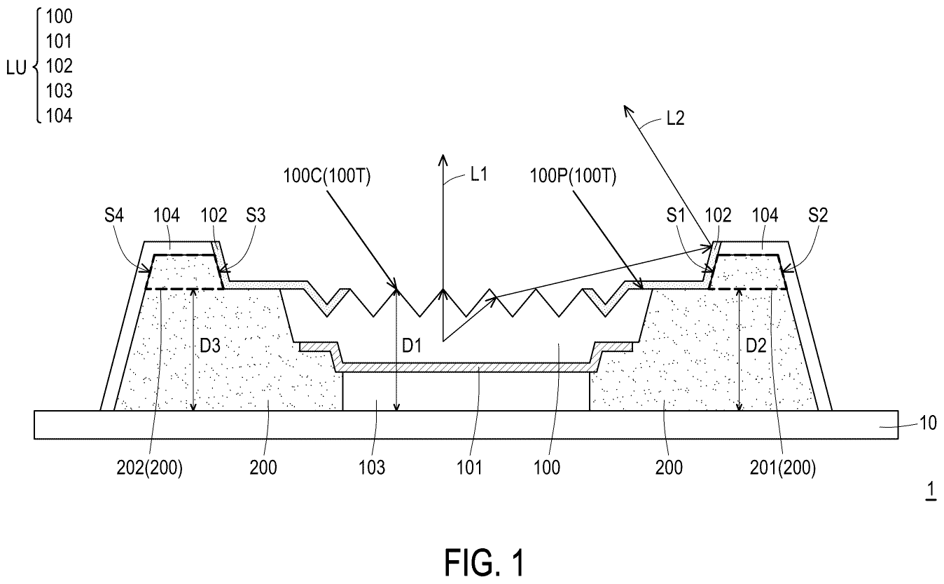

Referring to FIG. 1, FIG. 1 shows a schematic diagram of a display device according to an embodiment of the disclosure. A display device 1 includes a substrate 10 and multiple display pixels disposed on the substrate 10. Each display pixel includes at least one light emitting unit LU. Each light emitting unit LU includes a conductive layer 103, an ohmic contact metal 101, a light emitting diode 100, an ohmic contact metal 102, and a conductive layer 104. The ohmic contact metal 101 is electrically connected between the conductive layer 103 and the light emitting diode 100, the ohmic contact metal 102 is electrically connected between the conductive layer 104 and the light emitting diode 100, and the conductive layer 103 and the conductive layer 104 are electrically connected to the substrate. 10. The active layer of the light emitting diode 100 emits light (light L1 and light L2 shown in FIG. 1). In some embodiments, the light emitting unit LU may be any of a red light emitting unit that emits red light, a green light emitting unit that emits green light, and a blue light emitting unit that emits blue light.

Each display pixel also includes an insulating layer 200 disposed on at least one side of the at least one light emitting diode 100. The insulating layer 200 includes a protruding portion 201, where a distance D2 between the protruding portion 201 and the substrate 10 is greater than or equal to a distance D1 between a top surface 100T of the light emitting diode 100 and the substrate 10. In other words, relative to the substrate 10, the position of the protruding portion 201 is higher than the top surface 100T of the light emitting diode 100. At least a part of the ohmic contact metal 102 is disposed on a side wall S1 of the protruding portion 201 facing the light emitting diode 100. Therefore, this part of the ohmic contact metal 102 can reflect the light L2 from the top surface 100T, reduce the light leakage of the display device 1 at a large viewing angle, and improve the forward light emission of the display device 1.

According to the above, the display device 1 provided by the embodiment of the disclosure is configured with the protruding portion 201 located higher than the top surface 100T, and the ohmic contact metal 102 is disposed on the side wall S1 of the protruding portion 201 facing the light emitting diode 100. Utilizing the property of high reflectivity of the ohmic contact metal 102 in the visible light band, the light L2 from the light emitting diode 100 is reflected. Accordingly, the light leakage of the display device 1 at a large viewing angle is reduced, and the forward light emission of display device 1 is improved.

The top surface 100T of the light emitting diode 100 includes a central region 100C and a peripheral region 100P. The center of the top surface 100T is within the central region 100C, and the peripheral region 100P is located between the central region 100C and the side of the top surface 100T. In this embodiment, the ohmic contact metal 102 is disposed on the peripheral region 100P of the top surface 100T and exposes the central region 100C. This prevents the ohmic contact metal 102 from blocking the light generated by the light emitting diode 100 and improves the current efficiency of the light emitting unit LU.

It should be noted that in a comparative example, the display device does not reflect light by disposing ohmic contact metal on the protruding portion, and the ohmic contact metal is disposed in the central region of the top surface of the light emitting diode. In contrast, the display device 1 according to this embodiment is configured with the ohmic contact metal 102 on the side wall S1 of the protruding portion 201 to reflect light, and the ohmic contact metal 102 is not disposed on the central region 100C of the top surface 100T of the light emitting diode 100. As a result, the intensity of the display device 1 at the front viewing angle is increased by 118% to 213% compared to the comparative example, and its half-intensity viewing angle (i.e., the light intensity is half of the light intensity at the front viewing angle) can fall within the range of 55 degrees to 75 degrees compared to 75 degrees in the comparison example.

The conductive layer 104 is connected to the ohmic contact metal 102 and is disposed on the top surface of the protruding portion 201 away from the substrate 10 and on a side wall S2 to further electrically connect the substrate 10. In some embodiments, the conductive layer 104 may be a transparent conductive layer, but is not limited thereto.

Referring also to FIG. 1, in some embodiments, the insulating layer 200 can be disposed around the light emitting diode 100. The cross-sectional view shown in FIG. 1 can correspond to the horizontal viewing angle, the vertical viewing angle, and the viewing angle in any other direction of the display device 1.

The insulating layer 200 may also include a protruding portion 202, where a distance D3 between the protruding portion 202 and the substrate 10 is greater than or equal to the distance D1 between the top surface 100T of the light emitting diode 100 and the substrate 10. A manufacturing method of display device according to the embodiment of the disclosure may include patterning the insulating layer 200, and the size of the protruding portion 201 may be the same as or different from the size of the protruding portion 202. For example, the distance between the top surface of the protruding portion 201 away from the substrate 10 and the substrate 10 is not equal to the distance between the top surface of the protruding portion 202 away from the substrate 10 and the substrate 10.

In the embodiment shown in FIG. 1, the ohmic contact metal 102 can be disposed on a side wall S3 of the protruding portion 202 facing the light emitting diode 100 to reflect the light from the top surface 100T, reduce the light leakage of the display device 1 at a large viewing angle, and improve the forward light emission of the display device 1. In some embodiments, the size of the protruding portion 201 is different from the size of the protruding portion 202, and the areas of the ohmic contact metal 102 on the side wall S1 and the side wall S3 are different.

However, the disclosure is not limited thereto. In some embodiments, the ohmic contact metal 102 is disposed on the side wall S1 but not on the side wall S3. Accordingly, the brightness of the display device 1 at different viewing angles can be controlled. For example, for some viewing angle limitation needs or anti-peeking needs, a predetermined light field can be achieved by disposing the ohmic contact metal 102 on at least one of the side wall S1 of the protruding portion 201 and the side wall S3 of the protruding portion 202.

In some embodiments, the ohmic contact metal 102 is disposed on the side wall S1, and the side wall S3 is configured with a light-absorbing material. Accordingly, the brightness of the display device 1 at different viewing angles can be controlled. In this way, part of the light from the top surface 100T can be reflected by the ohmic contact metal 102 on the side wall S1, and another part of the light from the top surface 100T can be absorbed by the light-absorbing material on the side wall S3 to achieve a predetermined light field.

In some embodiments, the display device 1 may be used for in-car display. The light-absorbing material or the ohmic contact metal 102 is disposed on the side wall S1 (or the side wall S3) close to the driver, so as to absorb the light toward the driver or reflect the light toward the driver back to the direction of the forward viewing angle, thereby reducing the interference caused by the light to the driver. The light-absorbing material or the ohmic contact metal 102 can also be disposed on the side wall S1 (or the side wall S3) close to the windshield, so as to avoid reflection on the windshield.

In order to fully illustrate various implementation aspects of the disclosure, other embodiments of the disclosure are described below. It should be noted here that the following embodiments follow the reference numerals and part of the content of the previous embodiments, where the same reference numerals are used to represent the same or similar elements, and descriptions of the same technical content are omitted. For descriptions of omitted parts, reference may be made to the foregoing embodiments and will not be repeated in the following embodiments.

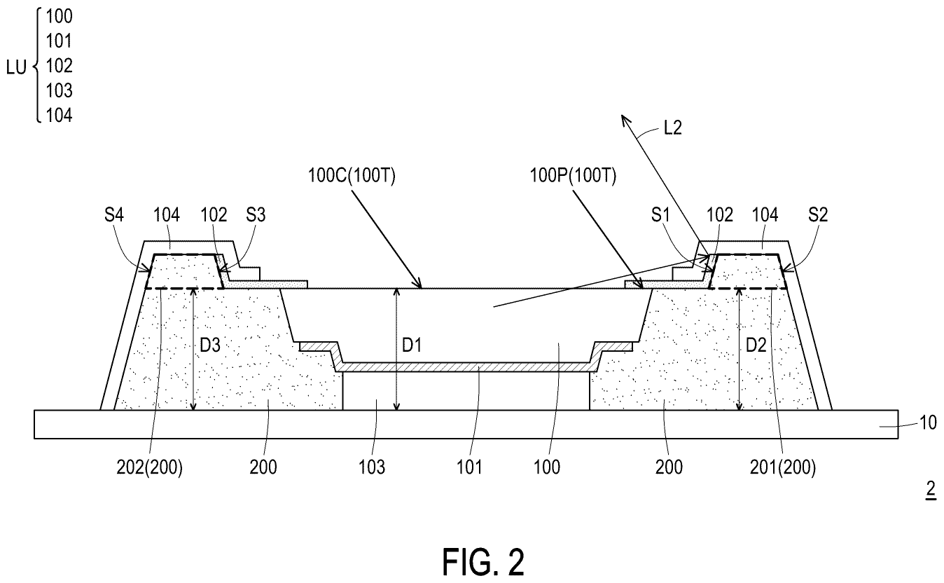

Referring to FIG. 2, FIG. 2 shows a schematic diagram of a display device according to an embodiment of the disclosure. A display device 2 includes a substrate 10 and multiple display pixels disposed on the substrate 10. Each display pixel includes at least one light emitting unit LU. Each light emitting unit LU includes a conductive layer 103, an ohmic contact metal 101, a light emitting diode 100, an ohmic contact metal 102, and a conductive layer 104.

The display device 2 of this embodiment is different from the display device 1 shown in FIG. 1 in that the conductive layer 104 is also disposed on the side wall S1 of the protruding portion 201 facing the light emitting diode 100 and the side wall S3 of the protruding portion 202 facing the light emitting diode 100, and covers the ohmic contact metal 102. The conductive layer 104 is a transparent conductive layer. Through the configuration shown in this embodiment, the bonding strength between the conductive layer 104 and the ohmic contact metal 102 can be improved.

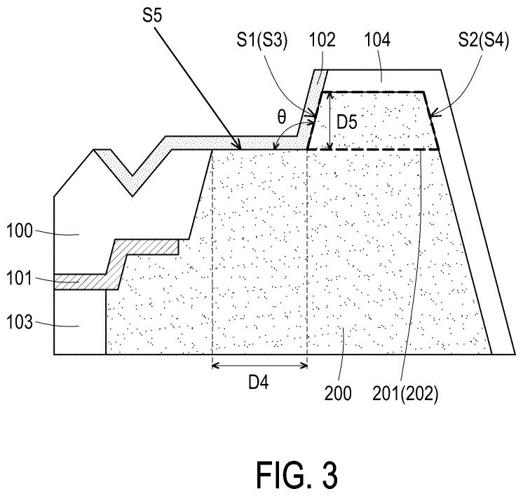

Next, referring to FIG. 3, FIG. 3 shows structural parameters of a display device according to an embodiment of the disclosure. For the display device of each of the aforementioned embodiments, the protruding portion 201 and the protruding portion 202 satisfy the following conditions. A distance D4 between the protruding portion 201 and the protruding portion 202 and the light emitting diode 100 is less than or equal to 4 microns; a thickness D5 of the protruding portion 201 and the protruding portion 202 in the normal direction of the substrate 10 is less than or equal to 10 microns; and the side wall S1 and the side wall S3 have a tilt angle θ, which falls within the range of 60 degrees to 120 degrees. The tilt angle θ refers to the angle between the side wall S1 and the side wall S3 and an insulating layer surface S5, where the insulating layer surface S5 is a plane parallel to the substrate 10. Specifically, the distance D4 between the protruding portion 201 and the protruding portion 202 and the light emitting diode 100 is as small as possible, such as 0 microns, to facilitate reflection of more light. In some preferred embodiments, the thickness D5 is less than or equal to 10 microns and greater than 4 microns, and the tilt angle θ falls within the range of 90 degrees to 120 degrees to facilitate reflection of more light.

It should be noted that in the embodiment of the disclosure, according to the predetermined light field, the parameter distance D4, thickness D5, and tilt angle θ of the protruding portion 201 as well as the parameter distance D4, thickness D5, and tilt angle θ of the protruding portion 202 can be the same as each other or different from each other. Moreover, whether to configure the ohmic contact metal 102 and the light-absorbing material on the side wall S1 and the side wall S3 can also be determined according to the predetermined light field.

To sum up, the display device provided by the embodiment of the disclosure is configured with a protruding portion that is higher than the top surface of the light emitting diode, and an ohmic contact metal is disposed on the side wall of the protruding portion facing the light emitting diode. Utilizing the property of high reflectivity of the ohmic contact metal in the visible light band, the light from the light emitting diode is reflected. Accordingly, the light leakage of the display device at a large viewing angle is reduced, and the forward light emission of display device is improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising a substrate and a plurality of display pixels disposed on the substrate, each of the display pixels comprising:
a light emitting unit, comprising a first ohmic contact metal, a light emitting diode, and a second ohmic contact metal disposed sequentially in a direction away from the substrate, wherein the first ohmic contact metal and the second ohmic contact metal are respectively connected to the light emitting diode; and
an insulating layer, disposed on at least one side of the light emitting diode, comprising a first protruding portion, wherein a distance between the first protruding portion and the substrate is greater than or equal to a distance between a top surface of the light emitting diode away from the substrate and the substrate, wherein
a part of the second ohmic contact metal is disposed on a first side wall of the first protruding portion facing the light emitting diode.

2. The display device according to claim 1, wherein the top surface of the light emitting diode comprises a central region and a peripheral region, wherein the central region is exposed from the second ohmic contact metal.

3. The display device according to claim 1, further comprising a conductive layer electrically connected between the second ohmic contact metal and the substrate, wherein at least a part of the conductive layer is disposed on a second side wall of the first protruding portion away from the light emitting diode.

4. The display device according to claim 3, wherein the conductive layer is also disposed on the first side wall of the first protruding portion facing the light emitting diode.

5. The display device according to claim 4, wherein the part of the second ohmic contact metal is located between the conductive layer and the first side wall, and the conductive layer is a transparent conductive layer.

6. The display device according to claim 1, wherein the insulating layer further comprises a second protruding portion, wherein a distance between the second protruding portion and the substrate is greater than or equal to a distance between the top surface of the light emitting diode and the substrate.

7. The display device according to claim 6, wherein another part of the second ohmic contact metal is disposed on a side wall of the second protruding portion facing the light emitting diode.

8. The display device according to claim 6, wherein the each of the display pixels further comprises a light-absorbing material disposed on a side wall of the second protruding portion facing the light emitting diode.

9. The display device according to claim 6, wherein the insulating layer is disposed around the light emitting diode.

10. The display device according to claim 1, wherein the first side wall has a tilt angle within a range of 90 degrees to 120 degrees, and a thickness of the first protruding portion in a normal direction of the substrate is less than or equal to 10 microns and greater than 4 microns.

11. The display device according to claim 1, wherein a distance between the first protruding portion and the light emitting diode is less than or equal to 4 microns.
